(19) United States
(12) Patent Application Publication
(10) Pub. No.: US 2025/0239988 A1
(43) Pub. Date: Jul. 24, 2025

(54) Vibrator Device And Method Of Manufacturing Same

(71) Applicant: SEIKO EPSON CORPORATION, Tokyo (JP)

(72) Inventor: Yusuke MATSUZAWA, Chino (JP)

(21) Appl. No.: 19/035,007

(22) Filed: Jan. 23, 2025

(30) Foreign Application Priority Data
Jan. 24, 2024 (JP) 2024-009046

(51) Int. Cl. H03H 9/05; H03B 5/36; H03H 3/02; H03H 9/10; H03H 9/19

(52) U.S. Cl. CPC H03H 9/0557; H03H 3/02; H03H 9/1021; H03H 9/19; H03B 5/36; H03H 2003/022

(57) ABSTRACT

A vibrator device includes a semiconductor substrate which includes a first surface and a second surface and is provided with a through hole penetrating the first surface and the second surface, a semiconductor circuit which is disposed at the second surface side and includes a conductive layer exposed in the through hole, a first interconnection which is disposed on an inner circumferential surface of the through hole and is electrically coupled to the conductive layer, a second interconnection which is disposed on the first surface and includes an interconnection layer smaller in surface roughness than the first interconnection and a covering layer covering the interconnection layer, and a vibrator which is located at the first surface side and is bonded to the second interconnection via a bonding member.

The present application is based on, and claims priority from JP Application Serial Number 2024-009046, filed Jan. 24, 2024, the disclosure of which is hereby incorporated by reference herein in its entirety.

### BACKGROUND

### 1. Technical Field

The present disclosure relates to a vibrator device and a method for manufacturing a vibrator device.

### 2. Related Art

For example, a semiconductor device disclosed in JP-A-2018-113466 includes a semiconductor substrate which includes an upper surface and a lower surface having a front and back relationship with each other, and is provided with a through hole penetrating both these surfaces, a first conductive layer which is disposed on the lower surface of the semiconductor substrate and is exposed in the through hole, an insulating layer disposed on an inner wall of the through hole, an organic insulating layer disposed on the insulating layer, and an interconnection which is disposed on the organic insulating layer and is electrically coupled to the first conductive layer via a second opening provided to the organic insulating layer. Further, the interconnection is formed so as to extend from the inside of the through hole to the upper surface of the semiconductor substrate.

JP-A-2018-113466 is an example of the related art.

When the semiconductor device having such a configuration is applied to an oscillator for oscillating a signal with a predetermined frequency, the oscillator is provided with a configuration including the semiconductor device described above, a vibrator which is located on the upper surface side of the semiconductor device and is bonded to the interconnection on the upper surface via a bonding member, and a lid member which is bonded to the upper surface of the semiconductor substrate and hermetically seals the vibrator in a space with the semiconductor substrate. However, in the semiconductor device disclosed in JP-A-2018-113466, a part of the interconnection disposed in the through hole and a part of the interconnection disposed on the upper surface are both formed by copper plating and have the same configuration, and therefore, a disconnection of the interconnection in the through hole or a bonding failure between the vibrator and the interconnection becomes apt to occur. That is, it is difficult to bond the vibrator and the interconnection in good condition while preventing the disconnection of the interconnection.

### SUMMARY

A vibrator device according to the present disclosure includes a semiconductor substrate which includes a first surface and a second surface having a front and back relationship with each other and is provided with a through hole penetrating the first surface and the second surface,
a semiconductor circuit which is disposed at the second surface side of the semiconductor substrate and includes a conductive layer exposed in the through hole,
a first interconnection which is disposed on an inner circumferential surface of the through hole and is electrically coupled to the conductive layer,
a second interconnection which is disposed on the first surface and includes an interconnection layer smaller in surface roughness than the first interconnection and a covering layer covering the interconnection layer, and
a vibrator which is located at the first surface side of the semiconductor substrate and is bonded to the second interconnection via a bonding member.

A method of manufacturing a vibrator device according to the present disclosure includes a preparation step of preparing a semiconductor device including a semiconductor substrate which includes a first surface and a second surface having a front and back relationship with each other and is provided with a through hole penetrating the first surface and the second surface and a semiconductor circuit which is disposed at the second surface side of the semiconductor substrate and includes a conductive layer exposed in the through hole,
a first interconnection forming step of forming a first interconnection to electrically be coupled to the conductive layer in the through hole by plate processing,
a second interconnection forming step of forming a second interconnection including an interconnection layer smaller in surface roughness than the first interconnection and a covering layer covering the interconnection layer on the first surface by sputtering, and
a vibrator bonding step of bonding a vibrator to the second interconnection via a bonding member.

### BRIEF DESCRIPTION OF THE DRAWINGS

FIG. 1 is a cross-sectional view showing a vibrator device according to a first embodiment.

FIG. 2 is an enlarged cross-sectional view of a through hole provided to a semiconductor substrate.

FIG. 3 is an enlarged cross-sectional view of a through hole provided to the semiconductor substrate.

FIG. 4 is a plan view showing an upper surface of a semiconductor device.

FIG. 5 is a cross-sectional view of the semiconductor device.

FIG. 6 is a plan view illustrating a vibrator.

FIG. 7 is a cross-sectional view illustrating a method of forming a bonding member.

FIG. 8 is a cross-sectional view illustrating a problem in plate processing.

FIG. 9 is a flowchart illustrating a manufacturing process of the vibrator device.

FIG. 10 is a cross-sectional view illustrating a method of manufacturing the vibrator device.

FIG. 11 is a cross-sectional view illustrating the method of manufacturing the vibrator device.

FIG. 12 is a cross-sectional view illustrating the method of manufacturing the vibrator device.

FIG. 13 is a cross-sectional view illustrating the method of manufacturing the vibrator device.

FIG. 14 is a cross-sectional view illustrating the method of manufacturing the vibrator device.

FIG. 15 is a cross-sectional view illustrating the method of manufacturing the vibrator device.

FIG. 16 is a cross-sectional view illustrating the method of manufacturing the vibrator device.

FIG. 17 is a cross-sectional view illustrating the method of manufacturing the vibrator device.

FIG. 18 is a cross-sectional view illustrating the method of manufacturing the vibrator device.

FIG. 19 is a cross-sectional view illustrating the method of manufacturing the vibrator device.

FIG. 20 is a cross-sectional view illustrating the method of manufacturing the vibrator device.

FIG. 21 is a cross-sectional view showing a vibrator device according to a second embodiment.

FIG. 22 is an enlarged cross-sectional view of a through hole provided to a semiconductor substrate.

FIG. 23 is an enlarged cross-sectional view of a through hole provided to the semiconductor substrate.

### DESCRIPTION OF EMBODIMENTS

A vibrator device and a method of manufacturing a vibrator device according to the present disclosure will hereinafter be described in detail based on some embodiments shown in the accompanying drawings.

### First Embodiment

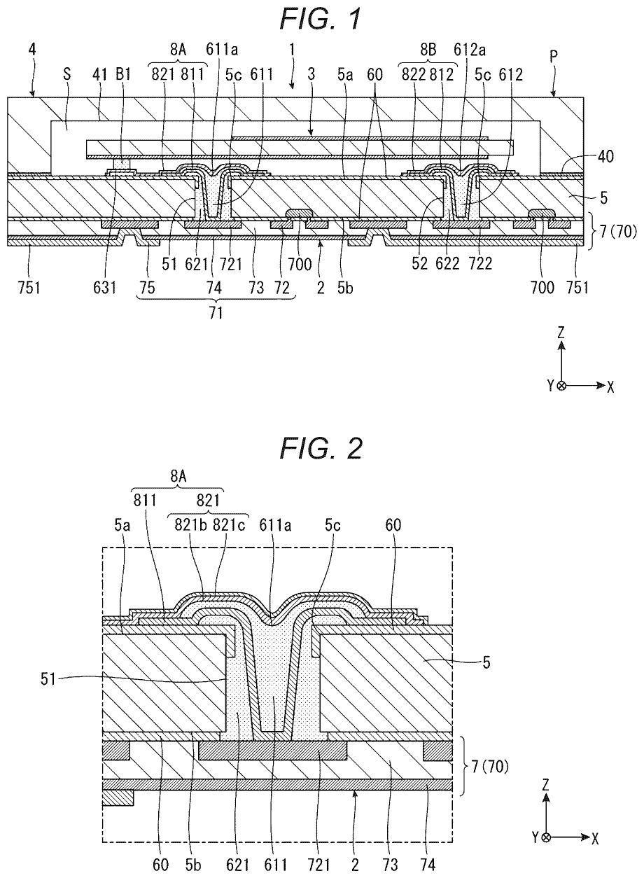

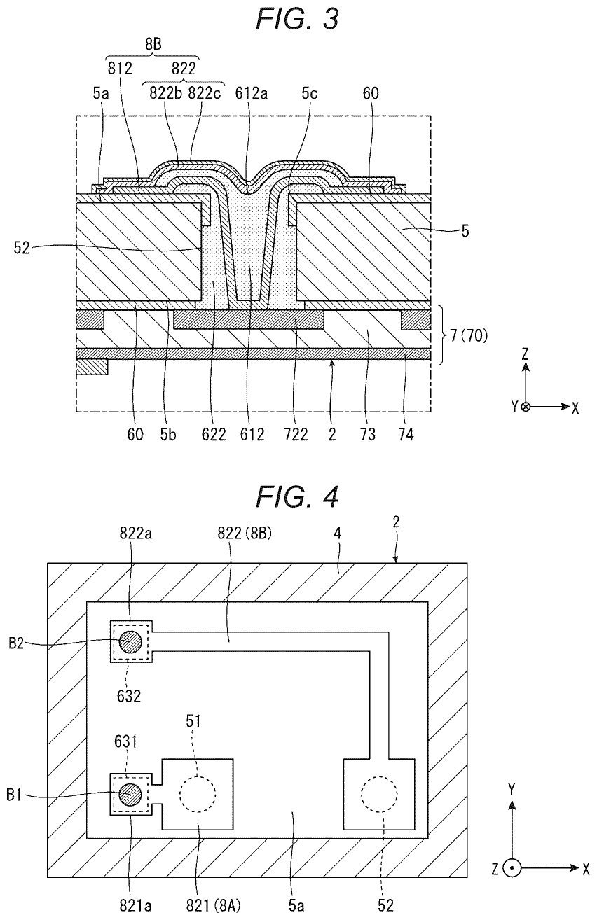

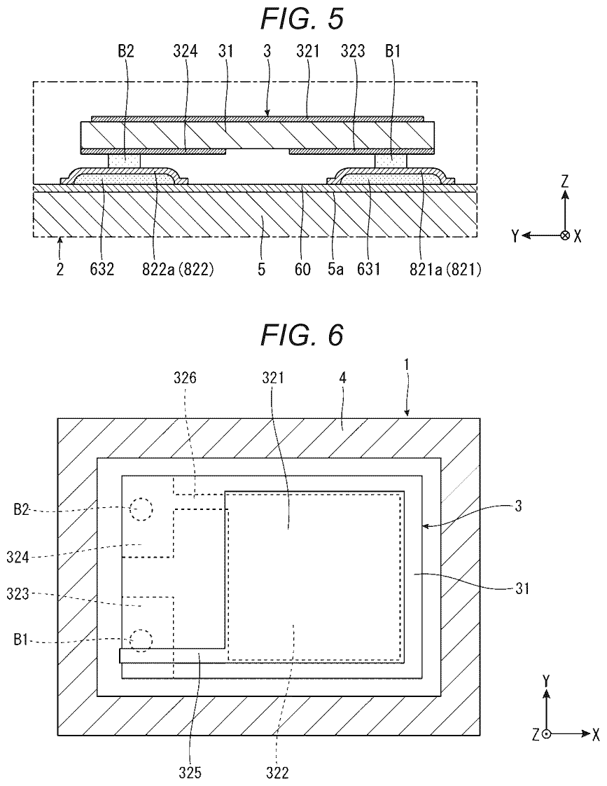

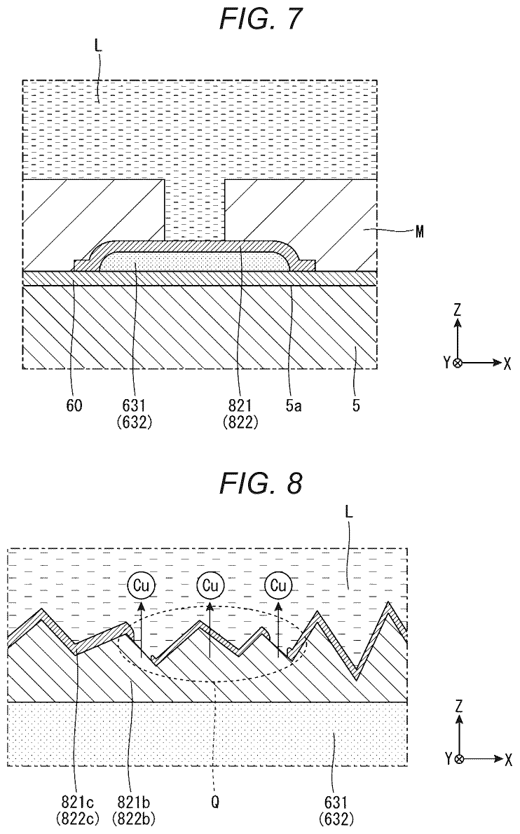

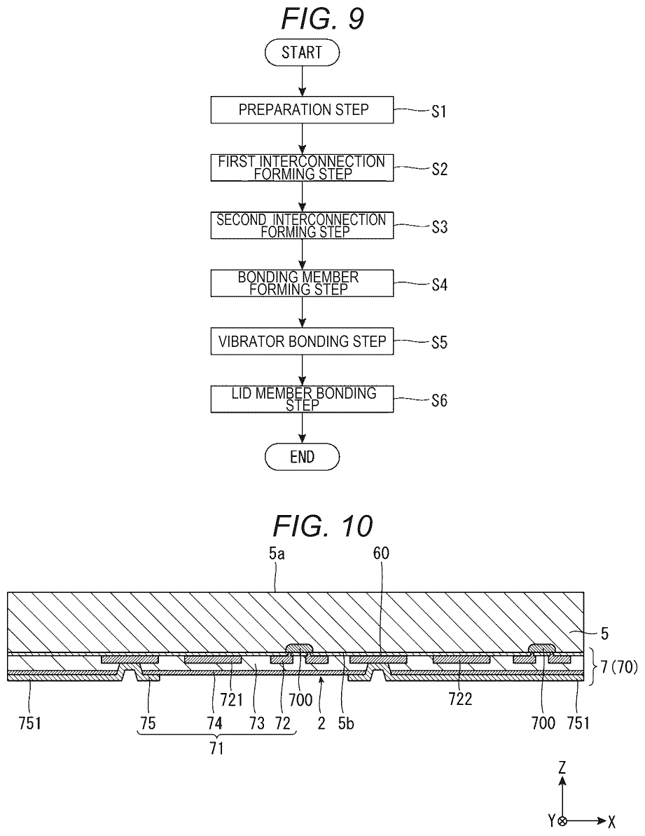

FIG. 1 is a cross-sectional view showing a vibrator device according to a first embodiment. FIGS. 2 and 3 are enlarged cross-sectional views of through holes provided to the semiconductor substrate, respectively. FIG. 4 is a plan view showing an upper surface of a semiconductor device. FIG. 5 is a cross-sectional view of the semiconductor device. FIG. 6 is a plan view showing a vibrator. FIG. 7 is a cross-sectional view illustrating a method of forming a bonding member. FIG. 8 is a cross-sectional view illustrating a problem in plate processing. FIG. 9 is a flowchart illustrating a manufacturing process of the vibrator device. FIGS. 10 to 20 are cross-sectional views illustrating a method of manufacturing the vibrator device. Note that three axes orthogonal to one another are shown as an X axis, a Y axis, and a Z axis for the sake of convenience of explanation. Further, the side pointed by the arrow in the Z-axis direction is also referred to as “upper side,” and the opposite side is also referred to as “lower side.” Further, a plan view from the Z-axis direction is also referred to simply as “plan view.”

As illustrated in FIG. 1, the vibrator device 1 includes a semiconductor device 2, a vibrator 3 disposed on an upper surface of the semiconductor device 2, and a lid member 4 bonded to the upper surface of the semiconductor device 2 so as to cover the vibrator 3. In such a vibrator device 1, a package P is formed with the semiconductor device 2 and the lid member 4, and the vibrator 3 is housed in a housing space S provided to the package P.

### Semiconductor Device 2

As shown in FIG. 1, the semiconductor device 2 includes a semiconductor substrate 5. The semiconductor substrate 5 is a silicon substrate. However, the semiconductor substrate 5 is not particularly limited, and a substrate made of a semiconductor material other than silicon, such as Ge, GaP, GaAs, or InP, may be used. Further, the semiconductor substrate 5 has an upper surface 5a as a first surface and a lower surface 5b as a second surface having a front and back relationship with each other. Further, a pair of through holes 51, 52 penetrating the upper surface 5a and the lower surface 5b are provided to the semiconductor substrate 5. The through holes 51, 52 can be formed by, for example, RIE (reactive ion etching). This makes it possible to form the through holes 51, 52 having high in aspect ratio. However, the method of forming the through holes 51, 52 is not particularly limited.

Further, the semiconductor device 2 includes insulating films 60 formed on the upper surface 5a and the lower surface 5b of the semiconductor substrate 5. Further, the insulating film 60 formed on the upper surface 5a enters the through holes 51, 52, and is also formed in upper end portions of the through holes 51, 52. The insulating films 60 are made of, for example, silicon oxide (SiO₂). The insulating films 60 can be formed d by, for example, sputtering. However, the constituent material of the insulating films 60 and the method of forming the insulating films 60 are not particularly limited.

Further, the semiconductor device 2 includes a semiconductor circuit 7 which is formed at the lower surface 5b side of the semiconductor substrate 5 and is electrically coupled to the vibrator 3. The semiconductor circuit 7 includes an oscillation circuit 70 that oscillates the vibrator 3 to generate a frequency of a reference signal such as a clock signal. Accordingly, the vibrator device 1 becomes an oscillator, and high versatility and demand can be expected.

The semiconductor circuit 7 includes a plurality of elements 700 formed on the lower surface 5b of the semiconductor substrate 5, and a stacked body 71 stacked on the lower surface 5b of the semiconductor substrate 5. The stacked body 71 includes an interconnection layer 72 formed on the lower surface 5b of the semiconductor substrate 5, an insulating layer 73 formed on a lower surface of the interconnection layer 72, a passivation film 74 formed on a lower surface of the insulating layer 73, and a terminal layer 75 formed on a lower surface of the passivation film 74. Further, the the plurality of elements 700 are electrically coupled to each other through a through electrode penetrating through interconnections provided to the interconnection layer 72 and interlayers to form the oscillation circuit 70. The elements 700 are, for example, transistors, resistors, capacitive elements, and so on.

In this way, by providing the semiconductor circuit 7 to the semiconductor substrate 5, it is possible to effectively use a space in the semiconductor substrate 5. Further, since the semiconductor circuit 7 can be integrally formed with the vibrator device 1, it is possible to achieve a reduction in size of a whole of the device. In particular, by forming the semiconductor circuit 7 at the lower surface 5b side, the region where the semiconductor circuit 7 can be formed is increased by the absence of the bonding region with the lid member 4 compared to when the semiconductor circuit 7 is formed at the upper surface 5a side. Therefore, a degree of design freedom of the semiconductor circuit 7 increases.

It should be noted that although the single interconnection layer 72 is provided to the stacked body 71 in the present embodiment, this is not a limitation, and it is possible to stack two or more interconnection layers 72 on one another via the insulating layers 73. In other words, the interconnection layer 72 and the insulating layer 73 may alternately be stacked a plurality of times between the semiconductor substrate 5 and the passivation film 74. This increases the degree of freedom in routing the interconnections to facilitate the circuit design.

Further, the interconnection layer 72 includes electrode pads 721 as a conductive layer that overlaps the through holes 51 and is exposed in the through holes 51, and electrode pads 722 as a conductive layer that overlaps the through holes 52 and is exposed in the through holes 52. Further, the terminal layer 75 includes a plurality of external terminals 751 for coupling the semiconductor circuit 7 to an external apparatus. Each of the external terminals 751 is electrically coupled to the interconnection layer 72 through the insulating layer 73 and the passivation film 74.

Further, as shown in FIGS. 1 to 3, the semiconductor device 2 includes second organic resin films 621, 622 arranged in the through holes 51, 52. The second organic resin films 621, 622 have an insulating property. Further, the second organic resin film 621 is disposed on an inner circumferential surface of the through hole 51 and covers the inner circumferential surface of the through hole 51. Similarly, the second organic resin film 622 is disposed on the inner circumferential surface of the through hole 52 and covers the inner circumferential surface of the through hole 52. In this way, by covering the inner circumferential surfaces of the through holes 51, 52 with the second organic resin films 621, 622, it is possible to more reliably insulate first interconnections 811, 812 from the semiconductor substrate 5.

Further, the second organic resin films 621, 622 protrude from upper openings of the through holes 51, 52 to the upper surface 5a, and cover a boundary portion 5c between the through holes 51, 52 and the upper surface 5a. Further, surfaces of portions of the second organic resin films 621, 622 that cover the boundary portion 5c are rounded. Further, inside the through holes 51, 52, the inner circumferential surfaces of the second organic resin films 621, 622 each have a tapered shape inner diameter of which gradually decreases from the upper side to the lower side.

The constituent material of such second organic resin films 621, 622 is not particularly limited, and for example, polyimide resin or epoxy resin can be used.

As shown in FIGS. 1 to 3, the semiconductor device 2 further includes first interconnections 811, 812 which are disposed inside the through holes 51, 52 and are electrically coupled to the electrode pads 721, 722. The first interconnection 811 is disposed on the inner circumferential surface of the second organic resin film 621 inside the through hole 51, and is electrically coupled to the electrode pad 721 via the lower opening of the through hole 51. The first interconnection 811 is disposed in the inner circumferential surface of the through hole 51. Further, a second organic resin film 621 is disposed between the inner circumferential surface of the through hole 51 and the first interconnection 811 inside the through hole 51.

Similarly, the first interconnection 812 is disposed in the inner circumferential surface of the second organic resin film 622 in the through hole 52, and is electrically coupled to the electrode pad 722 via the lower opening of the through hole 52. The first interconnection 812 is disposed in the inner circumferential surface of the through hole 52. Further, the second organic resin film 622 is disposed between the inner circumferential surface of the through hole 52 and the first interconnection 812 in the through hole 52.

Further, the first interconnections 811, 812 protrude from the upper openings of the through holes 51, 52 to the upper surface 5a and extend to the outside of the second organic resin films 621, 622. Note that as described above, since the portions covering the boundary portion 5c of the second organic resin films 621, 622 are rounded, a formation failure, damage, disconnection, and so on of the first interconnections 811, 812 in the boundary portion 5c can effectively be prevented. The first interconnections 811, 812 cover the through holes 51, 52 and the second organic resin films 621, 622 disposed in the through holes 51, 52, respectively. Further, portions of the first interconnections 811, 812 protruding to the upper surface 5a surround the through holes 51, 52 and the second organic resin films 621, 622 in a plan view.

The first interconnections 811, 812 are plated interconnections formed by electrolytic plate processing. By forming the first interconnections 811, 812 using electrolytic plate processing in this way, it becomes easy to form the first interconnections 811, 812 thick, and the disconnection of the first interconnections 811, 812 in the through holes 51, 52 can effectively be prevented. Further, high interlayer adhesiveness can be exerted. However, the plate processing is not limited to the electrolytic plate processing, and the first interconnections 811, 812 may be formed using electroless plate processing.

Here, in the electrolytic plate processing, a seed layer for growing plating in the through holes 51, 52 and on the upper surface 5a is formed by sputtering. Then, in the present embodiment, as described above, the inner circumferential surfaces of the second organic resin films 621, 622 are tapered to ensure the coverage of sputtering in forming the seed layer. Therefore, the seed layer can be formed with a desired thickness over the entire area, and as a result, the first interconnections 811, 812 can accurately be formed.

The constituent material of such first interconnections 811, 812 is not particularly limited, but copper (Cu), for example, can be used. Note that the description that the constituent material is copper (Cu) means that copper (Cu) is used as the main material, and as long as copper (Cu) is used as the main material, other materials may be added. Further, although the configuration of the seed layer is not particularly limited, it is possible to adopt a stacked body of, for example, a foundation layer formed of titanium-tungsten alloy (TiW) and a surface layer formed of copper (Cu).

As shown in FIGS. 1 to 3, the semiconductor device 2 further includes first organic resin films 611, 612 disposed so as to fill at least a part of the through holes 51, 52. The first organic resin films 611, 612 have an insulating property. The first organic resin film 611 is disposed on the first interconnection 811 and covers the first interconnection 811. Similarly, the first organic resin film 612 is disposed on the first interconnection 812 and covers the first interconnection 812. In this way, by covering the first interconnections 811, 812 with the first organic resin films 611, 612, it is possible to effectively suppress deterioration of electrical characteristics due to oxidation of the first interconnections 811, 812. Further, the airtightness of the housing space S can be improved by filling at least a part of the through holes 51, 52 with the first organic resin films 611, 612.

The first organic resin films 611, 612 protrude from the upper openings of the through holes 51, 52 to the upper surface 5a, and cover the first interconnections 811, 812 located on the upper surface 5a even around the through holes 51, 52. Therefore, the wider areas of the first interconnections 811, 812 are covered with the first organic resin films 611, 612, and the deterioration of the electrical characteristics of the first interconnections 811, 812 due to oxidation can more effectively be suppressed. Note that outer edge portions of the first interconnections 811, 812 are exposed from the first organic resin films 611, 612 to achieve electrical coupling to second interconnections 821, 822 described later. The first organic resin films 611, 612 cover the through holes 51, 52 and the first interconnections 811, 812 disposed in the through holes 51, 52, respectively. Further, portions of the first organic resin films 611, 612 protruding to the upper surface 5a surround the through holes 51, 52 in a plan view.

Further, on the surfaces of the first organic resin films 611, 612, there are recessed parts 611a, 612a recessed into the through holes 51, 52, respectively. Here, in the first organic resin films 611, 612, the film thickness in a central portion is made thicker than the film thickness in edge portions of the through holes 51, 52. Therefore, the recessed parts 611a, 612a are shallower than the through holes 51, 52 and gentle in inclination. Thus, the coverage of sputtering when forming the second interconnections 821, 822 described later can be ensured, and the second interconnections 821, 822 can be formed with high accuracy. Note that since the first organic resin films 611, 612 have the recessed parts 611a, 612a, the film thickness in the recessed parts 611a, 612a in the central portions of the first organic resin films 611, 612 is made thinner than that on the periphery. Further, the film thickness of the central portions is made thicker than the film thickness of the edge portions of the through holes 51, 52 located at the outer side thereof.

The constituent material of such first organic resin films 611, 612 is not particularly limited, and for example, polyimide resin or epoxy resin can be used similarly to the second organic resin films 621, 622 described above. In particular, by forming the first organic resin films 611, 612 and the second organic resin films 621, 622 with the same material, the linear expansion coefficients of these films become equal to each other, and it is possible to effectively prevent, for example, delamination.

As shown in FIGS. 1 to 3, the semiconductor device 2 further includes the second interconnections 821, 822 disposed on the upper surface 5a of the semiconductor substrate 5. The second interconnection 821 is electrically coupled to the first interconnection 811 by overlapping the outer edge portion of the first interconnection 811, that is, the portion exposed from the first organic resin film e 5a. Further, a single 611, on the upper surface interconnection 8A is configured with the first interconnection 811 and the second interconnection 821. According to such a configuration, the first interconnection 811 and the second interconnection 821 can easily be coupled to each other. Further, the portion in contact with the first interconnection 811 and the second interconnection 821 surrounds the through hole 51 and the second organic resin film 621 in a plan view. Similarly, the second interconnection 822 is electrically coupled to the first interconnection 812 by overlapping the outer edge portion of the first interconnection 812, that is, the portion exposed from the first organic resin film 612, on the upper surface 5a. Further, a single interconnection 8B is configured with the first interconnection 812 and the second interconnection 822. According to such a configuration, the first interconnection 812 and the second interconnection 822 can easily be coupled to each other. Further, the portion in contact with the first interconnection 812 and the second interconnection 822 surrounds the through hole 52 and the second organic resin film 622 in a plan view.

Further, as shown in FIG. 4, the second interconnections 821, 822 have internal terminals 821a, 822a which are disposed in one end portions thereof and to which the vibrator 3 is bonded.

Further, as shown in FIGS. 2 and 3, the second interconnections 821, 822 are also formed on the first organic resin films 611, 612 so as to cover the upper openings of the through holes 51, 52, and cover at least a part of the first interconnections 811, 812 via the first organic resin films 611, 612. Accordingly, outgas generated from the first interconnections 811, 812 can be confined in the through holes 51, 52 by the second interconnections 821, 822. Therefore, an environmental change of the housing space S due to the outgas, in particular, an increase in the pressure can be suppressed. Therefore, the vibration characteristics of the vibrator 3 are stabilized, and the vibrator device 1 having high reliability is obtained. In particular, in the present embodiment, the second interconnections 821, 822 cover the whole of the first interconnections 811, 812. Therefore, the advantages described above become more conspicuous.

The second interconnections 821, 822 are sputtering interconnections formed by sputtering. Further, the second interconnections 821, 822 are smaller in surface roughness and thinner in thickness than the first interconnections 811, 812. For example, the surface roughness of the second interconnections 821, 822 is one-tenth or less of that of the first interconnections 811, 812. By forming the second interconnections 821, 822 by sputtering, the occurrence of the outgas from the second interconnections 821, 822 can be suppressed. Therefore, it is possible to suppress an environmental change of the housing space S, in particular, an increase in pressure. Further, the second interconnections 821, 822 become dense films, and outgas generated from the first interconnections 811, 812 can more surely be confined in the through holes 51, 52. Note that as described above, at least a part of the through holes 51, 52 is filled with the first organic resin films 611, 612, and the recessed parts 611a, 612a which are shallower than the through holes 51, 52 and are gentle in inclination are formed on the surfaces of the first organic resin films 611, 612. Therefore, the coverage of the sputtering is ensured, and the second interconnections 821, 822 can be formed with high accuracy. Therefore, the second interconnections 821, 822 can more reliably cover the entire area of the first interconnections 811, 812 via the first organic resin films 611, 612.

As shown in FIGS. 2 and 3, the second interconnections 821, 822 are formed of a stacked body of interconnection layers 821b, 822b and covering layers 821c, 822c which are disposed so as to cover the interconnection layers 821b, 822b. Further, although not shown in the drawings, the interconnection layers 821b, 822b are formed of a stacked body of a foundation layer containing titanium-tungsten alloy (TiW) as a constituent material and an interconnection layer containing a copper (Cu) as constituent material. Further, although not shown, the covering layers 821c, 822c are formed of a stacked body of a foundation layer containing titanium (Ti) as a constituent material and a surface layer containing gold (Au) as a constituent material. In this way, by covering the outermost layer of the second interconnections 821, 822 with the surface layer formed of gold (Au), it is possible to effectively suppress deterioration of the electric characteristics due to oxidation of the second interconnections 821, 822.

As shown in FIG. 5, the semiconductor device 2 further includes third organic resin films 631, 632 disposed on the upper surface 5a of the semiconductor substrate 5. The third organic resin films 631, 632 have an insulating property. The third organic resin film 631 is interposed between the upper surface 5a and the internal terminal 821a of the second interconnection 821. In other words, the internal terminal 821a is formed on the third organic resin film 631 to cover the third organic resin film 631. Similarly, the third organic resin film 632 is interposed between the upper surface 5a and the internal terminal 822a of the second interconnection 822. In other words, the internal terminal 822a is formed on the third organic resin film 632 to cover the third organic resin film 632.

The constituent material of such third organic resin films 631, 632 is not particularly limited, and for example, polyimide resin or epoxy resin can be used similarly to the first organic resin films 611, 612 and the second organic resin films 621, 622 described above.

### Lid Member 4

As shown in FIG. 1, the lid member 4 includes a recessed part 41 that has a bottom, opens on a lower surface of the lid member 4, and houses the vibrator 3 inside. Further, the lower surface of the lid member 4 is bonded to the upper surface of the semiconductor device 2, that is, the upper surface 5a of the semiconductor substrate 5, via the bonding member 40. Thus, the housing space S for housing the vibrator 3 is formed between the lid member 4 and the semiconductor device 2. The housing space S is airtight and in a reduced pressure state, and is preferably in a state more approximate to vacuum. As a result, viscous resistance is reduced, and oscillation characteristics of the vibrator 3 are improved. However, an atmosphere in the housing space S is not particularly limited.

The lid member 4 is a silicon substrate similarly to the semiconductor substrate 5. As a result, linear expansion coefficients of the semiconductor substrate 5 and the lid member 4 become equal, generation of thermal stress caused by thermal expansion is prevented, and the vibrator device 1 having excellent vibration characteristics is obtained. Further, since the vibrator device 1 can be formed by a semiconductor process, the vibrator device 1 can be manufactured with high accuracy, and the size of the vibrator device 1 can be reduced. However, the lid member 4 is not particularly limited, and a substrate made of a semiconductor material other than silicon such as Ge, GaP, GaAs, or InP may be used.

### Vibrator 3

As shown in FIG. 6, the vibrator 3 includes a vibration substrate 31 and electrodes disposed on a surface of the vibration substrate 31. The vibration substrate 31 has a thickness-shear vibration mode, and is formed of an AT-cut quartz crystal substrate in the present embodiment. Since the AT-cut quartz crystal substrate has cubic frequency-temperature characteristics, the vibrator 3 having excellent temperature characteristics is obtained. Further, the electrode includes an excitation electrode 321 disposed on an upper surface of the vibration substrate 31 and an excitation electrode 322 disposed on a lower surface thereof so as to be opposed to the excitation electrode 321. Further, the electrode includes a pair of terminals 323, 324 disposed on the lower surface of the vibration substrate 31, an interconnection 325 that electrically couples the terminal 323 and the excitation electrode 321, and an interconnection 326 that electrically couples the terminal 324 and the excitation electrode 322.

Note that the configuration of the vibrator 3 is not limited to the configuration described above. For example, the vibrator 3 may have a mesa shape in which a vibration region sandwiched between the excitation electrodes 321, 322 protrudes from the periphery thereof, or conversely, the vibration region may have an inverted mesa shape in which the vibration region is recessed from the periphery thereof. Further, bevel machining in which the periphery of the vibration substrate 31 is ground, or convex machining in which the upper surface and the lower surface are made into convex surfaces may be performed.

Further, the vibrator 3 is not limited to one that vibrates in the thickness-shear vibration mode, and may be, for example, a vibrator in which a plurality of vibrating arms makes a flexural vibration in an in-plane direction. That is, the vibration substrate 31 is not limited to one formed from the AT-cut quartz crystal substrate, and may be formed of a quartz crystal substrate other than the AT-cut quartz crystal substrate such as an X-cut quartz crystal substrate, a Y-cut quartz crystal substrate, a Z-cut quartz crystal substrate, a BT-cut quartz crystal substrate, an SC-cut quartz crystal substrate, or an ST-cut quartz crystal substrate. Further, although the vibration substrate 31 is made of quartz crystal in the present embodiment, this is not a limitation, and the vibration substrate 31 may be formed of a piezoelectric single crystal body made of lithium niobate, lithium tantalate, lithium tetraborate, langasite crystal, potassium niobate, or gallium phosphate, or may be formed of a piezoelectric single crystal body made of other materials than those described above. Furthermore, the vibrator 3 is not limited to vibrator of a piezoelectric drive type, and may be a vibrator of an electrostatic drive type using electrostatic force.

As shown in FIG. 5, such a vibrator 3 is bonded to the internal terminals 821a, 822a with bonding members B1, B2 having conductivity. The bonding member B1 electrically couples the internal terminal 821a and the terminal 323, and the bonding member B2 electrically couples the internal terminal 822a and the terminal 324. Thus, the vibrator 3 and the semiconductor circuit 7 are electrically coupled to each other via the bonding members B1, B2 and the interconnections 8A, 8B.

Such bonding members B1, B2 are micro-bumps formed by electrolytic plate processing. In this way, by forming the bonding members B1, B2 by the electrolytic plate processing, the fine bonding members B1, B2 can be formed. Therefore, a reduction in size of the vibrator device 1 can be achieved. However, the bonding members B1, B2 may be formed by electroless plate processing. Further, the constituent material of the bonding members B1, B2 is not particularly limited, but in the present embodiment, gold (Au) is used. Accordingly, the bonding members B1, B2 which have excellent conductivity while suppressing the deterioration of the electrical characteristics due to oxidation are obtained.

As illustrated in, for example, FIG. 7, the bonding members B1, B2 are formed by depositing a mask M having openings in the locations where the bonding members B1, B2 are formed, and then applying a voltage in a state in which the semiconductor device 2 is dipped in the plating liquid L. Here, as shown in FIG. 8, when the surface roughness of the interconnection layers 821b, 822b of the second interconnections 821, 822 is large, the covering layers 821c, 822c are not homogenously formed on the surface of the interconnection layers 821b, 822b, and there is a possibility that an abnormal portion Q such as a portion thin in film thickness or a through hole is formed in the covering layers 821c, 822c. In this way, when the abnormal portion Q is formed in the covering layers 821c, 822c, when the semiconductor device 2 is immersed in the plating liquid L, the interconnection layers 821b, 822b are dissolved in the plating liquid L via the abnormal portion Q, and copper (Cu), which is a constituent material of the interconnection layers 821b, 822b, is mixed with the bonding members B1, B2. In this way, when copper (Cu) is mixed with the bonding members B1, B2, since the purity of gold (Au) degrades, the bonding strength between the bonding members B1, B2 and the vibrator 3 is reduced, and as a result, the mechanical strength of the vibrator device 1 is reduced. Such a problem is apt to occur when, for example, the interconnection layers 821b, 822b are formed by plate processing.

In contrast, by forming the interconnection layers 821b, 822b by sputtering as in the present embodiment, the surface roughness of the interconnection layers 821b, 822b can be made smaller than the surface roughness of the first interconnections 811, 812 which are plated interconnections. Therefore, the surface roughness of the interconnection layers 821b, 822b can be reduced to a sufficiently low level, and the abnormal portion Q becomes hard to be formed in the covering layers 821c, 822c. Therefore, the problem described above can effectively be suppressed. That is, according to the vibrator device 1 related to the present embodiment, mixing of copper (Cu) into the bonding members B1, B2 is prevented, and the reduction in bonding strength between the bonding members B1, B2 and the vibrator 3 can effectively be prevented. Therefore, it is possible to prevent the reduction in mechanical strength of the vibrator device 1.

The configuration of the vibrator device 1 is described hereinabove. In such a vibrator device 1, the interconnections 8A, 8B for electrically coupling the vibrator 3 and the semiconductor circuit 7 to each other are formed of the first interconnections 811, 812 and the second interconnections 821, 822 formed separately from each other. Therefore, in the first interconnections 811, 812, it is possible to adopt a design in which the disconnection in the through holes 51, 52 can sufficiently be prevented, and in the second interconnections 821, 822, it is possible to adopt a design in which bonding between the second interconnections 821, 822 and the vibrator 3 becomes favorable. Therefore, according to the vibrator device 1, it is possible to effectively prevent the disconnection of the interconnections 8A, 8B in the through holes 51, 52 and the bonding failure between the vibrator 3 and the interconnections 8A, 8B, and thus it is possible to exert a high reliability.

Then, a method of manufacturing the vibrator device 1 will be described. As shown in FIG. 9, the method of manufacturing the vibrator device 1 includes a preparation step S1 of preparing the semiconductor device 2, a first interconnection forming step S2 of forming the first interconnections 811, 812 by plate processing, a second interconnection forming step S3 of forming the second interconnections 821, 822 by sputtering, a bonding member forming step S4 of forming the bonding members B1, B2 by plate processing, a vibrator bonding step S5 of bonding the vibrator 3 to the semiconductor device 2 via the bonding members B1, B2, and a lid member bonding step S6 of bonding the lid member 4 to the semiconductor device 2.

### Preparation Step S1

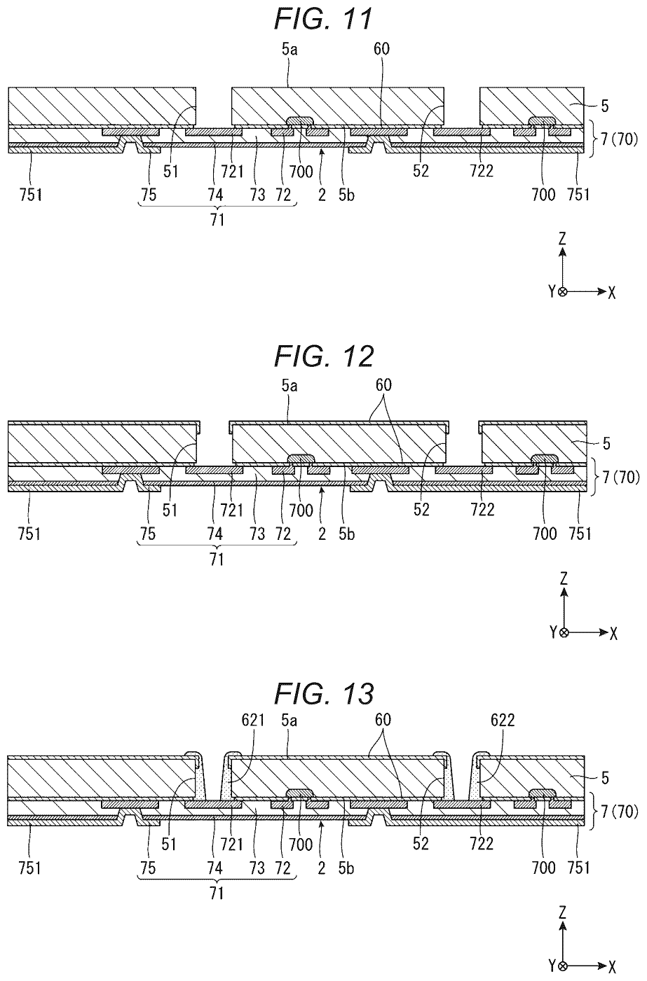

First, as shown in FIG. 10, the semiconductor substrate 5 is prepared, and the semiconductor circuit 7 is formed at the lower surface 5b side. Then, as necessary, the semiconductor substrate 5 is ground and polished from the upper surface 5a side, and the semiconductor substrate 5 is thinned to a predetermined thickness. Then, as shown in FIG. 11, the through holes 51, 52 reaching the electrode pads 721, 722 are provided to the semiconductor substrate 5. The through holes 51, 52 can be formed by, for example, RIE (reactive ion etching). Then, for example, the insulating film 60 is formed from the upper surface 5a side of the semiconductor substrate 5 by sputtering, and unnecessary portions of the insulating film 60 are removed by etching to thereby expose the electrode pads 721, 722 in the through holes 51, 52 as shown in FIG. 12.

### First Interconnection Forming Step S2

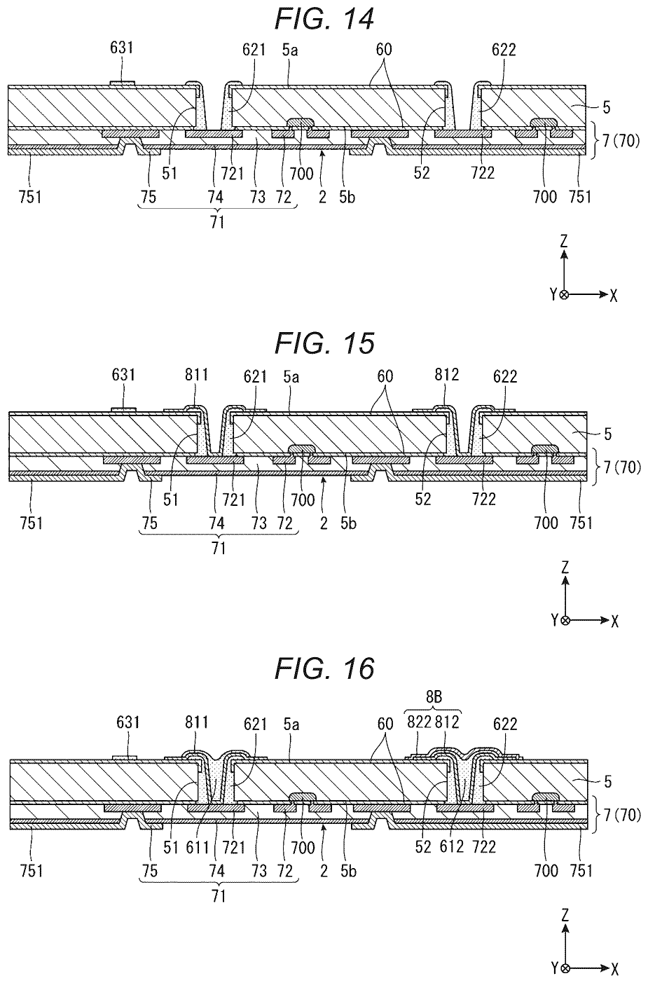

Then, organic resin is applied to the inner circumferential surfaces of the through holes 51, 52 and the upper surface 5a, and the organic resin thus applied is heated to be cured (baked), and is then patterned to thereby form the second organic resin films 621, 622 as shown in FIG. 13. Note that since the organic resin flows downward due to its own weight when the organic resin is applied, the inner circumferential surfaces of the second organic resin films 621, 622 thus formed have the tapered shapes. Then, organic resin is applied to the upper surface 5a, and the organic resin thus applied is heated to be cured (baked) and is then patterned to thereby form the third organic resin films 631, 632 as shown in FIG. 14. However, in FIG. 14, the third organic resin film 632 is not illustrated. Note that this is not a limitation, and the second organic resin films 621, 622 may be formed after the third organic resin films 631, 632 are formed, or these films may be formed at the same time.

Then, as shown in FIG. 15, the first interconnections 811, 812 are formed on the inner circumferential surfaces of the through holes 51, 52 and the upper surface 5a by electrolytic plate processing from above the second organic resin films 621, 622. By forming the first interconnections 811, 812 thick, it is possible to effectively prevent disconnection of the first interconnections 811, 812 in the through holes 51, 52. Note that although not shown in the drawings, the step of forming the first interconnections 811, 812 includes, for example, a step of forming the seed layer on the surface of the semiconductor substrate 5 by sputtering, a step of forming a mask having openings corresponding to the first interconnections 811, 812 on the seed layer, a step of growing the plating in the opening of the mask to form the first interconnections 811, 812, and a step of etching and removing unnecessary portions of the seed layer after removing the mask. As described above, since the inner circumferential surfaces of the second organic resin films 621, 622 have the tapered shapes, the coverage of sputtering is ensured, and the seed layer can be formed with high accuracy.

### Second Interconnection Forming Step S3

Then, organic resin is applied on the first interconnections 811, 812, and the organic resin thus applied is heated to be cured (baked) and is then patterned to thereby form the first organic resin films 611, 612 as shown in FIG. 16. Thus, at least a part of the through holes 51, 52 is filled.

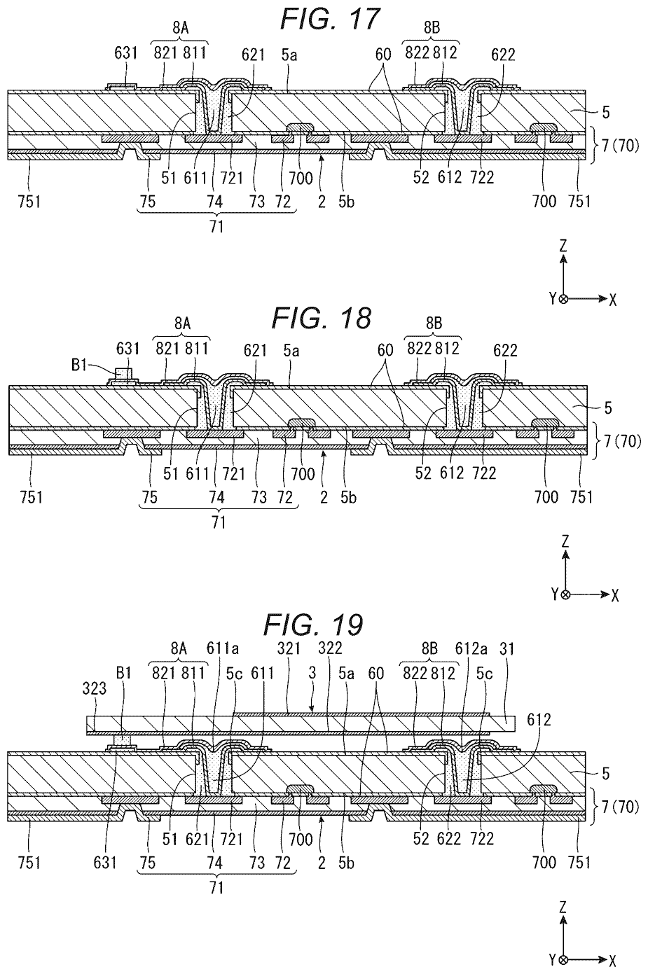

Then, as shown in FIG. 17, the second interconnections 821, 822 are formed on the upper surface 5a by sputtering from above the first organic resin films 611, 612, and the first interconnections 811, 812 are covered with the second interconnections 821, 822. Accordingly, the outgas generated from the first interconnections 811, 812 can be confined in the through holes 51, 52. Note that since the through holes 51, 52 are filled with the first organic resin films 611, 612 prior to this step, the coverage of sputtering is ensured in this step, and the second interconnections 821, 822 can accurately be formed.

Although not shown in the drawings, the step of forming the second interconnections 821, 822 includes a step of forming the foundation layer of the interconnection layers 821b, 822b by sputtering and then patterning the foundation layer, a step of forming the interconnection layer of the interconnection layers 821b, 822b by sputtering and then patterning the interconnection layer, a step of forming the foundation layer of the covering layers 821c, 822c by sputtering and then patterning the foundation layer, and a step of forming the surface layer of the covering layers 821c, 822c by sputtering and then patterning the surface layer.

### Bonding Member Forming Step S4

Then, as shown in FIG. 18, the bonding members B1, B2 are formed on the internal terminals 821a, 822a of the second interconnections 821, 822 by electrolytic plate processing. However, in FIG. 18, the bonding member B2 is not illustrated. The method of forming the bonding members B1, B2 is as described above. As described above, since the interconnection layers 821b, 822b of the second interconnections 821, 822 are formed by sputtering, the surface roughness of the interconnection layers 821b, 822b can be reduced to a sufficiently low level. Therefore, it is hard for the abnormal portion Q to be formed in the covering layers 821c, 822c on the interconnection layers 821b, 822b, and it is possible to effectively prevent the interconnection layers 821b, 822b from being dissolved in the plating liquid L. As a result, copper (Cu), which is a material of the second interconnections 821, 822, is hard to be mixed with the bonding members B1, B2, and the bonding members B1, B2 made of high-purity gold (Au) can be formed.

### Vibrator Bonding Step S5

Then, as shown in FIG. 19, the vibrator 3 is bonded to the internal terminals 821a, 822a by pressing the vibrator 3 against the bonding members B1, B2 to perform pressure bonding. On this occasion, the third organic resin films 631, 632 formed immediately below the internal terminals 821a, 822a function as stress relaxation layers that relax the stress generated when pressing the vibrator 3. Therefore, it is possible to reduce the stress applied to the semiconductor device 2 in the present step, and it is possible to effectively prevent the damage of the semiconductor device 2.

### Lid Member Bonding Step S6

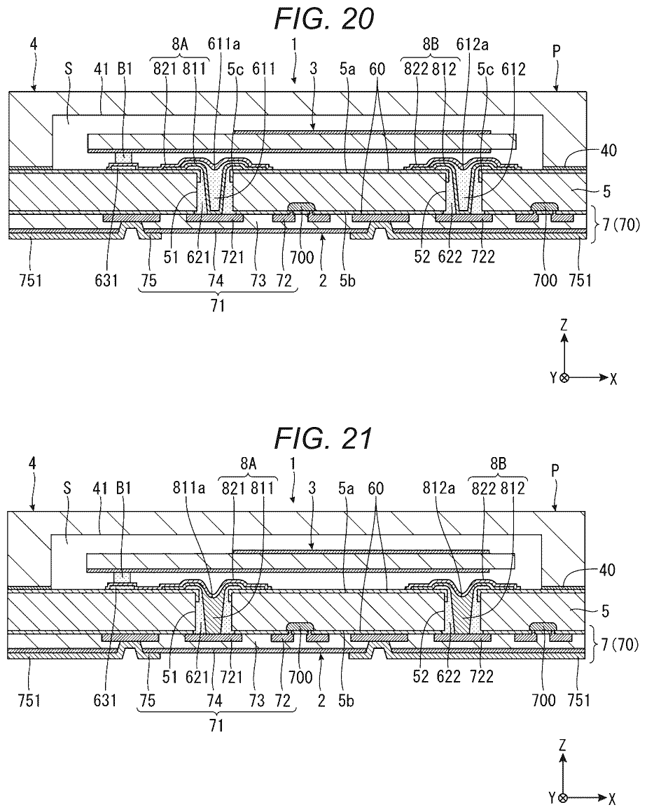

Then, as shown in FIG. 20, the lid member 4 is bonded to the upper surface 5a of the semiconductor substrate 5 in a reduced pressure state.

In this way, the vibrator device 1 is obtained. According to such a method of manufacturing the vibrator device 1, the outgas generated from the first interconnections 811, 812 can be confined in the through holes 51, 52 by the second interconnections 821, 822. Therefore, an environmental change of the housing space S due to the outgas, in particular, an increase in pressure can be prevented. Therefore, the vibration characteristics of the vibrator 3 are stabilized, and the vibrator device 1 having high reliability is obtained.

The vibrator device 1 is described hereinabove. As described above, such a vibrator device 1 includes the semiconductor substrate 5 which includes the upper surface 5a as the first surface and the lower surface 5b as the second surface in the front and back relationship with each other, and which is provided with the through holes 51, 52 penetrating the upper surface 5a and the lower surface 5b, the semiconductor circuit 7 which is disposed at the lower surface 5b side of the semiconductor substrate 5 and includes the electrode pads 721, 722 as the conductive layers exposed in the through holes 51, 52, the first interconnections 811, 812 which are disposed on the inner circumferential surfaces of the through holes 51, 52 and are electrically coupled to the electrode pads 721, 722, the second interconnections 821, 822 which are disposed on the upper surface 5a and include the interconnection layers 821b, 822b lower in surface roughness than the first interconnections 811, 812 and the covering layers 821c, 822c covering the interconnection layers 821b, 822b, and the vibrator 3 which is located at the upper surface 5a side of the semiconductor substrate 5 and is bonded to the second interconnections 821, 822 via the bonding members B1, B2. According to such a configuration, for example, by forming the first interconnections 811, 812 sufficiently thick, it is possible to effectively prevent disconnection of the first interconnections 811, 812 in the through holes 51, 52. Further, since the surface roughness of the interconnection layers 821b, 822b of the second interconnections 821, 822 is smaller than the surface roughness of the first interconnections 811, 812, the bonding strength between the second interconnections 821, 822 and the vibrator 3 can sufficiently be increased. Therefore, according to the vibrator device 1, it is possible to effectively prevent the disconnection of the interconnections 8A, 8B in the through holes 51, 52 and the bonding failure between the vibrator 3 and the interconnections 8A, 8B, and thus it is possible to exert a high reliability.

Further, as described above, in the vibrator device 1, the first interconnections 811, 812 are plated interconnections, and the second interconnections 821, 822 are sputtered interconnections. According to such a configuration, it becomes easy to form the first interconnections 811, 812 sufficiently thick. Further, the surface roughness of the second interconnections 821, 822 can be made small.

Further, as described above, the first interconnections 811, 812 protrude to the upper surface 5a, and the second interconnections 821, 822 are in contact with the first interconnections 811, 812 on the upper surface 5a. By adopting such a configuration, the first interconnections 811, 812 and the second interconnections 821, 822 can easily be coupled.

Further, as described above, the second interconnections 821, 822 cover the first interconnections 811, 812. According to such a configuration, the outgas generated from the first interconnections 811, 812 can be confined in the through holes 51, 52 by the second interconnections 821, 822. Therefore, an environmental change of the housing space S due to the outgas, in particular, an increase in pressure can be prevented. Therefore, the vibration characteristics of the vibrator 3 are stabilized, and the vibrator device 1 having high reliability is obtained.

Further, as described above, the vibrator device 1 includes the first organic resin films 611, 612 interposed between the first interconnections 811, 812 and the second interconnections 821, 822 in the through holes 51, 52. By adopting such a configuration, the first interconnections 811, 812 are covered with the first organic resin films 611, 612, and oxidation of the first interconnections 811, 812 is prevented. Therefore, it is possible to effectively suppress the deterioration of the electrical characteristics of the first interconnections 811, 812, for example, an increase in the resistance value. Further, at least a part of the through holes 51, 52 can be filled with the first organic resin films 611, 612, and the airtightness of the housing space S can also be improved. Furthermore, by filling at least a part of the through holes 51, 52 with the first organic resin films 611, 612, it is possible to ensure the coverage of sputtering in forming the second interconnections 821, 822. Therefore, the second interconnections 821, 822 can accurately be formed.

Further, as described above, the first organic resin films 611, 612 protrude to the upper surface 5a. By adopting such a configuration, a wider area of the first interconnections 811, 812 is covered with the first organic resin films 611, 612, and the deterioration of the electrical characteristics of the first interconnections 811, 812 due to oxidation can more effectively be prevented.

Further, as described above, the vibrator device 1 includes the second organic resin films 621, 622 interposed between the inner circumferential surfaces of the through holes 51, 52 and the first interconnections 811, 812. By adopting such a configuration, the first interconnections 811, 812 and the semiconductor substrate 5 can more reliably be insulated.

Further, as described above, the second organic resin films 621, 622 protrude to the upper surface 5a. By adopting such a configuration, the boundary portion 5c between the through holes 51, 52 and the upper surface 5a is covered with the second organic resin films 621, 622 and rounded. Therefore, damage, disconnection, and so on of the first interconnections 811, 812 in the boundary portion 5c can effectively be prevented.

Further, as described above, the vibrator device 1 includes the third organic resin films 631, 632 interposed between the upper surface 5a and the second interconnections 821, 822, and the vibrator 3 is bonded to the second interconnections 821, 822 via the bonding members B1, B2 in the portion overlapping the third organic resin films 631, 632. By adopting such a configuration, the stress generated when bonding the vibrator 3 is relaxed by the third organic resin films 631, 632, and becomes hard to be applied to the semiconductor device 2. Therefore, breakage of the semiconductor device 2 can effectively be prevented.

Further, as described above, the semiconductor circuit 7 includes the oscillation circuit 70 that oscillates the vibrator 3. By adopting such a configuration, the vibrator device 1 becomes an oscillator, and high versatility and demand can be expected.

Further, as described above, the method of manufacturing the vibrator device 1 includes the preparation step S1 of preparing the semiconductor device 2 including the semiconductor substrate 5 which includes the upper surface 5a as the first surface and the lower surface 5b as the second surface having the front and back relationship and is provided with the through holes 51, 52 penetrating the upper surface 5a and the lower surface 5b, and the semiconductor circuit 7 which is disposed at the lower surface 5b side of the semiconductor substrate 5 and includes the electrode pads 721, 722 as the conductive layers exposed in the through holes 51, 52, the first interconnection forming step S2 of forming the first interconnections 811, 812 electrically coupled to the electrode pads 721, 722 in the through holes 51, 52 by the plate processing, the second interconnection forming step S3 of forming, on the upper surface 5a by sputtering, the second interconnections 821, 822 including the covering layers 821c, 822c covering the interconnection layers 821b, 822b and the interconnection layers 821b, 822b smaller in surface roughness than the first interconnections 811, 812, and the vibrator bonding step S5 of bonding the vibrator 3 to the second interconnections 821, 822 via the bonding members B1, B2. According to such a manufacturing method, it is possible to effectively prevent the disconnection of the first interconnections 811, 812 in the through holes 51, 52 by, for example, forming the first interconnections 811, 812 sufficiently thick in the first interconnection forming step S2. Further, since the interconnection layers 821b, 822b smaller in surface roughness than the first interconnections 811, 812 can be formed in the second interconnection forming step S3, the second interconnections 821, 822 and the vibrator 3 can more strongly be bonded in the vibrator bonding step S5. Therefore, it is possible to obtain the vibrator device 1 capable of effectively preventing the disconnection of the interconnections 8A, 8B in the through holes 51, 52 and the bonding failure between the vibrator 3 and the interconnections 8A, 8B to exert the high reliability.

### Second Embodiment

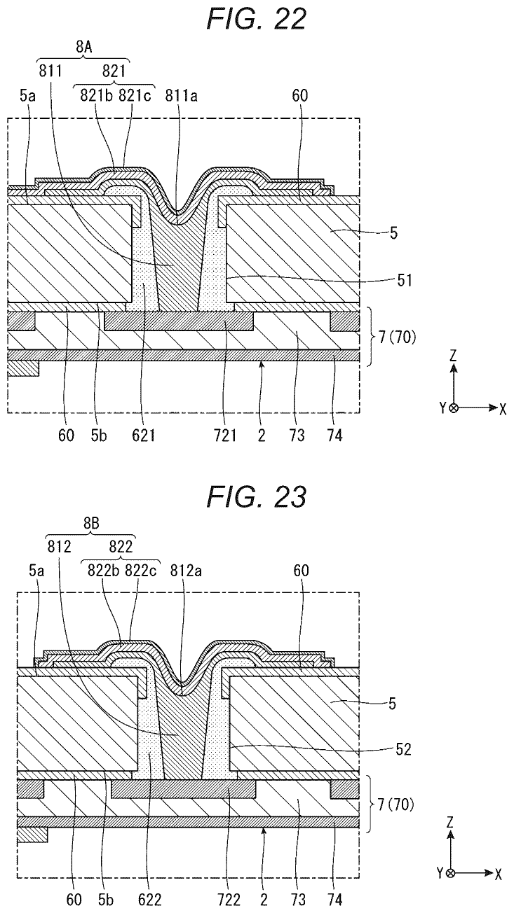

FIG. 21 is a cross-sectional view illustrating a vibrator device according to a second embodiment. FIGS. 22 and 23 are each an enlarged cross-sectional view of through holes provided to the semiconductor substrate.

The vibrator device 1 according to the present embodiment is substantially the same as the vibrator device 1 according to the first embodiment described above except that the configuration of the semiconductor device 2 is different therefrom. Note that in the following description, the vibrator device 1 according to the present embodiment will be described focusing on differences from the first embodiment described above, and description on substantially the same matters will be omitted. Further, in the drawings of the present embodiment, the same reference numerals are given to configurations substantially the same as those in the embodiment described above.

As shown in FIGS. 21 to 23, in the semiconductor device 2 of the present embodiment, the first organic resin films 611, 612 are omitted from the first embodiment described above, and the through holes 51, 52 are filled with the first interconnections 811, 812 so as to compensate for the first organic resin films 611, 612 thus omitted. Accordingly, it is possible to effectively prevent the disconnection of the first interconnections 811, 812 in the through holes 51, 52.

Further, in the through holes 51, 52, the film thickness of the first interconnections 811, 812 is made thicker in the central portion than in the edge portions of the through holes 51, 52. Further, the film thickness of the first interconnections 811, 812 in the central portions of the through holes 51, 52 is made thinner than the depth of the through holes 51, 52. Therefore, recessed parts 811a, 812a recessed in the through holes 51, 52 are formed on the upper surfaces of the first interconnections 811, 812. The recessed parts 811a, 812a are made shallower than the through holes 51, 52 and gentle in inclination. Therefore, the coverage of sputtering when forming the second interconnections 821, 822 can be ensured, and the second interconnections 821, 822 can be formed with high accuracy. Note that since the first interconnections 811, 812 have the recessed parts 811a, 812a, the film thickness in the recessed parts 811a, 812a is made thinner in the central portions of the first interconnections 811, 812 than on the periphery of the central portions. Further, the film thickness of the central portions is made thicker than the film thickness of the edge portions of the through holes 51, 52 located at the outer side thereof.

As described above, in the vibrator device 1 according to the present embodiment, the film thickness of the first interconnections 811, 812 is thicker in the central portion than in the edge portions of the through holes 51, 52. By adopting such a configuration, it is possible to effectively prevent the disconnection of the first interconnections 811, 812 in the through holes 51, 52. Further, the coverage of sputtering when forming the second interconnections 821, 822 can be ensured, and the second interconnections 821, 822 can be formed with high accuracy.

According also to such a second embodiment, substantially the same advantages as those of the first embodiment described above can be exerted.

Although the vibrator device and the method of manufacturing the vibrator device are described hereinabove based on the embodiments shown in the accompanying drawings, the present disclosure is not limited thereto, and the configurations of the constituents and the steps can be replaced with any configurations and steps having substantially the same functions. Further, any other configurations or steps may be added to the present disclosure. Further, the present disclosure may be a combination of two or more embodiments.

Further, although the example in which the vibrator device 1 is applied to the oscillator is described in the embodiments described above, the application example of the vibrator device 1 is not particularly limited, and the vibrator device 1 can be applied to an inertial sensor such as an acceleration sensor or an angular velocity sensor. Further, the vibrator device 1 can be applied to any devices besides the above.

What is claimed is:

1. A vibrator device comprising:
a semiconductor substrate which includes a first surface and a second surface having a front and back relationship with each other and is provided with a through hole penetrating the first surface and the second surface;
a semiconductor circuit which is disposed at the second surface side of the semiconductor substrate and includes a conductive layer exposed in the through hole;
a first interconnection which is disposed on an inner circumferential surface of the through hole and is electrically coupled to the conductive layer;
a second interconnection which is disposed on the first surface and includes an interconnection layer smaller in surface roughness than the first interconnection and a covering layer covering the interconnection layer; and
a vibrator which is located at the first surface side of the semiconductor substrate and is bonded to the second interconnection via a bonding member.

2. The vibrator device according to claim 1, wherein
the first interconnection is a plated interconnection, and
the second interconnection is a sputtered interconnection.

3. The vibrator device according to claim 1, wherein
the first interconnection a part of the first wiring is disposed above the first surface, and
the second interconnection is in contact with the first interconnection on the first surface.

4. The vibrator device according to claim 1, wherein
the second interconnection covers the first interconnection.

5. The vibrator device according to claim 4, further comprising:
a first organic resin film interposed between the first interconnection and the second interconnection in the through hole.

6. The vibrator device according to claim 5, wherein
a portion of the first organic resin film is disposed above the first surface.

7. The vibrator device according to claim 3, further comprising:
a second organic resin film interposed between the inner circumferential surface of the through hole and the first interconnection.

8. The vibrator device according to claim 7, wherein
a portion of the second organic resin film is disposed above the first surface.

9. The vibrator device according to claim 1, further comprising:
a third organic resin film interposed between the first surface and the second interconnection, wherein
the vibrator is bonded to the second interconnection via the bonding member in a portion overlapping the third organic resin film.

10. The vibrator device according to claim 1, wherein
a film thickness of the first interconnection is thicker in a central portion than in an edge portion of the through hole.

11. The vibrator device according to claim 1, wherein
the semiconductor circuit includes an oscillation circuit that oscillates the vibrator.

12. A method of manufacturing a vibrator device comprising:
a preparation step of preparing a semiconductor device including a semiconductor substrate which includes a first surface and a second surface having a front and back relationship with each other and is provided with a through hole penetrating the first surface and the second surface and a semiconductor circuit which is disposed at the second surface side of the semiconductor substrate and includes a conductive layer exposed in the through hole;
a first interconnection forming step of forming a first interconnection to electrically be coupled to the conductive layer in the through hole by plate processing;
a second interconnection forming step of forming a second interconnection including an interconnection layer smaller in surface roughness than the first interconnection and a covering layer covering the interconnection layer on the first surface by sputtering; and
a vibrator bonding step of bonding a vibrator to the second interconnection via a bonding member.
